(19) United States
(12) Patent Application Publication
(10) Pub. No.: US 2023/0034792 A1
(43) Pub. Date: Feb. 2, 2023

(54) CURRENT SENSOR

(71) Applicant: Alps Alpine Co., Ltd., Tokyo (JP)

(72) Inventors: Manabu TAMURA, Miyagi-ken (JP); Mitsuo ARATONO, Tokyo (JP)

(21) Appl. No.: 17/964,464

(22) Filed: Oct. 12, 2022

Related U.S. Application Data
(63) Continuation of application No. PCT/JP2021/019826, filed on May 25, 2021.

(30) Foreign Application Priority Data
May 27, 2020 (JP) 2020-092674

(51) Int. Cl. G01R 15/20

(52) U.S. Cl. CPC G01R 15/207; G01R 15/205

(57) ABSTRACT

A current sensor has: a magnetism detection unit that can detect a component, in a first direction, of a magnetic field generated when a current flows in a current path; a shield member that can block an external magnetic field; a circuit board on which the magnetism detection unit is mounted; and a fixing member, composed of a magnetic material, that fixes the shield member to the circuit board. The first direction is parallel to the front surface of the circuit board. The shield member has two opposing plates placed so that their plate surfaces face each other in the first direction. The magnetism detection unit is placed by being interposed between the two opposing plates in the first direction. The fixing member extends toward both sides of the magnetism detection unit in the first direction when viewed along the normal of the front surface of the circuit board.

### CLAIM OF PRIORITY

This application is a Continuation of International Application No. PCT/JP2021/019826 filed on May 25, 2021, which claims benefit of Japanese Patent Application No. 2020-092674 filed on May 27, 2020. The entire contents of each application noted above are hereby incorporated by reference.

### BACKGROUND OF THE INVENTION

### 1. Field of the Invention

The present invention relates to a current sensor that detects a current under measurement according to a magnetic field generated when the current under measurement flows in a current path.

### 2. Description of the Related Art

A current sensor described in Japanese Patent No. 6540802 has a magnetic sensor that detects the strength of a magnetic field generated by a current under measurement, a circuit board on which this magnetic sensor is mounted, and an arch-like magnetic substance portion fixed on the circuit board so as to surround the magnetic sensor. The magnetic substance portion includes a ceiling portion and a pair of leg portions that protrude from the ceiling portion with a spacing between them and are in contact with the circuit board. These leg portions extend in a direction along the detection axis of the magnetic sensor and are placed so as to sandwich the magnetic sensor between them. The leg portions of the magnetic substance portion are bonded to the circuit board with an adhesive or by soldering. Alternatively, the magnetic substance portion is resin-sealed in a package together with the magnetic sensor. Since the magnetic sensor is covered with the magnetic substance portion in this way, the influence of an external magnetic field on the magnetic sensor is suppressed.

However, since the current sensor described in Japanese Patent No. 6540802 has a structure in which the magnetic substance portion is arched and a pair of openings are formed in a direction orthogonal to the detection axis of the magnetic sensor, the influence of the external magnetic field may not be insufficiently reduced. Another problem is that since the magnetic substance portion is provided so as to further cover the magnetic sensor mounted on the circuit board from above, the circuit board is large in size in the direction of the normal of the circuit board. Furthermore, in the structure in which the magnetic substance portion is fixed with an adhesive or in another way, the end or the like of the leg portion is bonded to the circuit board with an adhesive or in another way, in which case the fixing area is small. Therefore, there has been the fear that the fixing strength is lowered.

### SUMMARY OF THE INVENTION

In view of this, the present invention provides a current sensor that can more greatly suppress the influence of an external magnetic field, can achieve a low profile in the direction of the normal of the circuit board, and can enhance the strength of fixing to the circuit board.

To solve the problems described above, a current sensor in the present invention has: a magnetism detection unit that can detect a component of a magnetic field generated when a current flows in a current path, the component being in a first direction; a shield member that can block an external magnetic field; a circuit board on which the magnetism detection unit is mounted; and a fixing member composed of a magnetic material, the fixing member fixing the shield member to the circuit board. The first direction is parallel to the front surface of the circuit board. The shield member has two opposing plates placed so that their plate surfaces face each other in the first direction. The magnetism detection unit is placed by being interposed between the two opposing plates in the first direction. The fixing member is provided so as to extend toward both sides of the magnetism detection unit in the first direction when viewed along the normal of the front surface of the circuit board.

Due to the structure in which the magnetism detection unit is interposed between the two opposing plates and the fixing member extends toward both sides of the magnetism detection unit in the first direction, the magnetism detection unit is less likely to be affected by the external magnetic field and a current sensor having high shield performance can thereby be implemented.

In the current sensor in the present invention, the shield member preferably has a linking portion that links one ends of the two opposing plates together. Therefore, the positional relationship between the two opposing plates can be surely maintained and the external magnetic field directed to the magnetism detection unit can be blocked in a range as well in which the linking portion is disposed. This enables shield performance to be further enhanced.

In the current sensor in the present invention, a direction that is parallel to the front surface of the circuit board and is orthogonal to the first direction is preferably taken as a second direction; the fixing member is preferably placed at least on one side of the shield member in the second direction when viewed along the normal of the front surface of the circuit board; and the fixing member and shield member are preferably integrally formed from a single part. Therefore, the stability of the shield member in fixing can be enhanced, and since the shield member is enclosed by the fixing member in the second direction, shield performance can be further enhanced.

In the current sensor in the present invention, the fixing member is preferably placed on both sides of the shield member in the second direction when viewed along the normal of the front surface of the circuit board. Therefore, both the stability of the shield member in fixing and the shield performance can be further enhanced.

In the current sensor in the present invention, the fixing member preferably has: two extending portions provided so as to extend toward both sides of the magnetism detection unit in the first direction, one toward each side, when viewed along the normal of the front surface of the circuit board; and an intermediate portion that links the two extending portions together. The fixing member and shield member are preferably connected to each other through the linking portion and intermediate portion. Therefore, the fixing member can be simply manufactured by molding or in another way, separately from the shield member.

In the current sensor in the present invention, the intermediate portion is preferably placed so as to be stacked on the linking portion in a direction along the normal of the front surface of the circuit board. Therefore, an occupied area on the circuit board can be reduced.

In the current sensor in the present invention, the two opposing plates are preferably members that are independent of each other, and are preferably linked together through the fixing member. Therefore, the shield member can be simply manufactured.

In the current sensor in the present invention, the circuit board preferably has two surfaces, which are a front surface and a rear surface parallel to the front surface, and it is preferable for the magnetism detection unit to be mounted on one surface of the two surfaces and for the linking portion to be placed on the other surface of the two surfaces. Therefore, a low profile can be achieved in a direction along the normal of the front surface of the circuit board when compared with a structure in which the magnetism detection unit is placed on the circuit board and the shield member is further placed above the magnetism detection unit.

In the current sensor in the present invention, the current path is preferably formed on the circuit board as a circuit pattern. Therefore, the current path can be easily and precisely formed and a low profile can be achieved.

The present invention can provide a current sensor that can more greatly suppress the influence of an external magnetic field, can achieve a low profile in the direction of the normal of the circuit board, and can enhance the strength of fixing to the circuit board.

### BRIEF DESCRIPTION OF THE DRAWINGS

FIG. 1 is a perspective view illustrating the structure of a current sensor according to a first embodiment;

FIG. 2A is a plan view illustrating the structure of the current sensor according to the first embodiment, and FIG. 2B is a sectional view along line IIB-IIB in FIG. 2A;

FIG. 3 is a perspective view illustrating the structure of a current sensor according to a second embodiment;

FIG. 4A is a plan view illustrating the structure of the current sensor according to the second embodiment, and FIG. 4B is a sectional view along line IVB-IVB in FIG. 4A;

FIG. 5A is a plan view illustrating the structure of a current sensor according to a third embodiment, and FIG. 5B is a sectional view along line VB-VB in FIG. 5A; and

FIG. 6A is a plan view illustrating the structure of a current sensor according to a fourth embodiment, and FIG. 6B is a sectional view along line VIB-VIB in FIG. 6A.

### DESCRIPTION OF THE PREFERRED EMBODIMENTS

The current sensor according to embodiments of the present invention will be described below in detail with reference to the drawings.

In each drawing, the first direction D1 is a direction parallel to the front surface 40a of a circuit board 40. One of the components of a magnetic field generated when a current flows in a current path is along the first direction D1. A direction in which the normal of the front surface 40a of the circuit board 40 on which the magnetic sensor 20 is mounted and the normal of a rear surface 40b parallel to the front surface 40a extend is a normal direction N. The first direction D1 is a direction parallel to the front surface 40a of the circuit board 40. The second direction D2 may be a direction that is parallel to the front surface 40a of the circuit board 40 and is orthogonal to the first direction D1. In the description below, a state viewed from the same side as the front surface 40a of the circuit board 40 along the normal direction N may be referred to as a plan view.

### First Embodiment

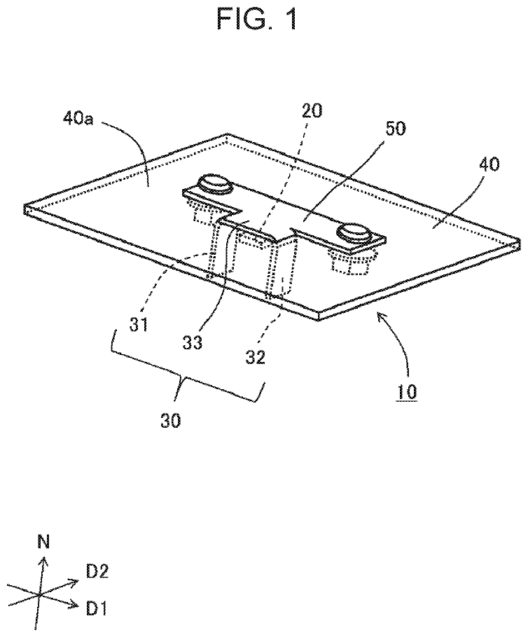

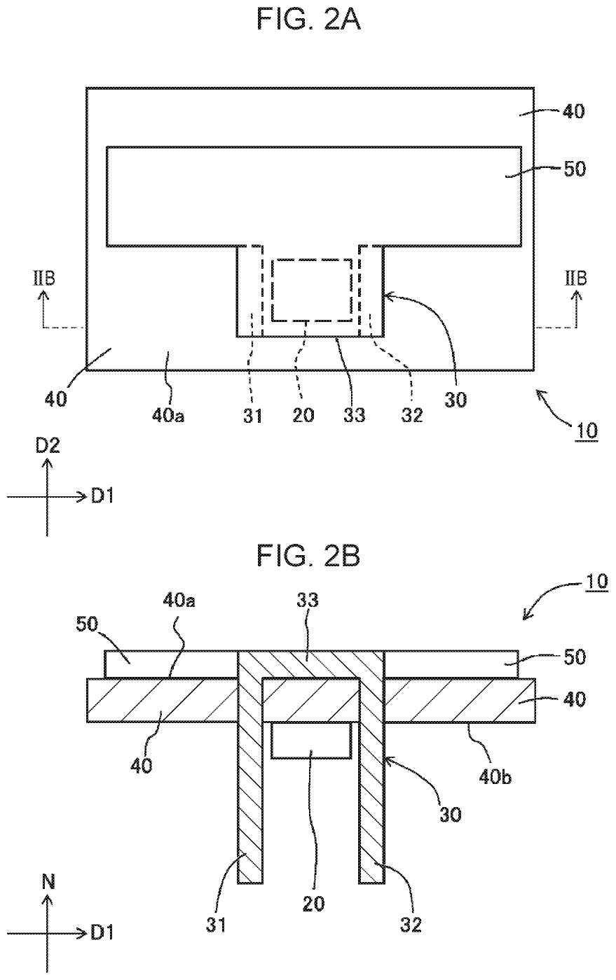

FIG. 1 is a perspective view illustrating the structure of a current sensor 10 according to a first embodiment. FIG. 2A is a plan view illustrating the structure of the current sensor 10 according to the first embodiment, and FIG. 2B is a sectional view along line IIB-IIB in FIG. 2A. In FIGS. 2A and 2B, the structure illustrated in FIG. 1 is simplified for explanation of explanation.

As illustrated in FIGS. 2A and 2B, the current sensor 10 has a magnetic sensor 20 used as a magnetism detection unit, a shield member 30, the circuit board 40, and a fixing member 50.

As illustrated in FIGS. 2A and 2B, the magnetic sensor 20 is mounted on the rear surface 40b of the circuit board 40 in a rectangular shape in plan view. A current path (not illustrated) may be provided on the front surface 40a of the circuit board 40 as a circuit pattern. As for the circuit board 40 and current path, a double-sided printed-wiring board is used as the circuit board 40 and circuit patterns are formed on a base board by patterning metal foils, which are, for example, copper foils. An example of the base board is an epoxy resin base board including glass or a ceramic wiring board.

To form the current path, it is also possible to place a bus bar, which is formed from a metal plate separately from the circuit board 40, on the front surface 40a of the circuit board 40.

The magnetic sensor 20 is placed so that it can detect at least a component, in the first direction D1, of a magnetic field generated when a current flows in the above current path. Therefore, the magnetic sensor 20 is placed on the circuit board 40 so that the direction of the sensitivity axis of the magnetic sensor 20 matches the first direction D1. In the example illustrated in FIGS. 2A and 2B, the current path and magnetic sensor 20 are placed so that the direction along the long sides of the circuit board 40 in a rectangular shape matches the first direction D1.

The shield member 30 and fixing member 50 may be integrally formed from a single part. Specifically, they may be formed by bending a single plate made of a magnetic material to a predetermined shape. Examples of the above magnetic material include Permalloy, silicon steel, and soft magnetic iron.

The shield member 30 and fixing member 50 in this embodiment are integrally formed by machining a single plate that extends along in the first direction D1 and has a rectangular shape in plan view. Cutouts parallel to the first direction D1 are formed from both ends of the plate in the first direction D1 toward the center. The shield member 30 is formed by bending the resulting portions of the plate, each of which has a rectangular shape in plan view and is on the front side (lower side in FIG. 2A) in the second direction D2 with respect to these cutouts, on the side on which there are no cutouts, along virtual lines parallel to the second direction D2. Due to this bending, the shield member 30 has two opposing plates 31 and 32 extending downward along the normal direction N and may also have a linking portion 33 that links the upper ends (one ends on the upper side in the up-down direction) of these opposing plates 31 and 32 together. The two opposing plates 31 and 32 have the same shape and are placed so that their plate surfaces face each other in a state in which they are parallel to each other in the first direction D1. The linking portion 33 extends along the circuit board 40 in the first direction D1.

The fixing member 50 is continuous to the linking portion 33 of the shield member 30 so as to form the same plane together with the linking portion 33. The fixing member 50 has a rectangular shape extending in the first direction D1 in plan view. The fixing member 50 extends to the outside of both sides of the linking portion 33 in the first direction D1 when viewed along the normal direction N.

The fixing member 50 and shield member 30 are fixed to the circuit board 40 by, for example, forming through-holes extending through the fixing member 50 in its thickness direction at both ends of the fixing member 50 in the first direction D1 and at part, of the circuit board 40, corresponding to both ends of the fixing member 50 in the first direction D1, inserting fixing screws in the through-holes, and screwing the fixing screws into the circuit board 40. Due to this fixing, the fixing member 50 and the linking portion 33 of the shield member 30 are brought into contact with the front surface 40a of the circuit board 40. In this state, the two opposing plates 31 and 32 of the shield member 30 pass through the through-holes, formed in the circuit board 40 for the two opposing plates 31 and 32, in its thickness direction, and further extend downward from the rear surface 40b of the circuit board 40 along the normal direction N.

A structure is also possible in which the fixing member 50 is fixed to the circuit board 40 by placing an adhesive between the fixing member 50 and circuit board 40 instead of the above fixing screws or in addition to the above fixing screws.

The magnetic sensor 20 mounted on the rear surface 40b of the circuit board 40 is placed so as to be interposed between the two opposing plates 31 and 32, which extend from the rear surface 40b, in the first direction D1. Therefore, at least a component, along the first direction D1, of the external magnetic field directed to the magnetic sensor 20 is blocked. As described above, the magnetic sensor 20 is placed so that it can detect at least a component, in the first direction D1, of a magnetic field generated when a current flows in the above current path. Therefore, the influence of noise (a component of the external magnetic field) on the to-be-detected component of the magnetic field is lessened, enabling the component of the magnetic field to be precisely measured.

Furthermore, the linking portion 33 is placed above the magnetic sensor 20, the fixing member 50 is placed so that the fixing member 50 and shield member 30 are arranged side by side in the second direction D2, and the fixing member 50 extends to the outside of both sides of the linking portion 33 in the first direction D1. Therefore, the external magnetic field directed to the magnetic sensor 20 can be blocked by the linking portion 33 and fixing member 50 as well. This type of structure enables a current sensor having high shield performance against the external magnetic field to be implemented.

Since the fixing member 50 and the linking portion 33 of the shield member 30 are fixed to the front surface 40a of the circuit board 40 in contact with the front surface 40a, the profile can be greatly lowered when compared with a structure in which a magnetic sensor is placed on a circuit board and a shield member is further placed above the magnetic sensor as in the conventional current sensor. The effect of the low profile is further increased because sequential placement on the front surface 40a of the circuit board 40 can be avoided by mounting the magnetic sensor 20 on the rear surface 40b of the circuit board 40 and placing the linking portion 33 on the front surface 40a in contact with it.

Since the rear surfaces of the fixing member 50 and linking portion 33 are fixed to the front surface 40a of the circuit board 40 in surface contact with the front surface 40a, high strength in fixing is achieved.

In the structure described above, the fixing member 50 and the linking portion 33 of the shield member 30 have been placed on the front surface 40a of the circuit board 40 and the magnetic sensor 20 has been placed on the rear surface 40b. However, this may be reversed: the magnetic sensor 20 may be placed on the front surface 40a and the linking portion 33 and fixing member 50 may be placed on the rear surface 40b.

Here, simulation results in an example and a comparative example will be described about effects when an external magnetic field is given to the current sensor 10 in the first embodiment.

### Example 1

When an external magnetic field with a magnetic flux density of 1 mT was given to the current sensor 10 having a shape described below, an increase of 0.8% was seen when compared with a case in which no external magnetic field was given.

The shape of each portion in the simulation in example 1 was as follows:

Shape of the opposing plates 31 and 32: 6 mm in width, 10 mm in length, 0.8 mm in thickness;

Material of the shield member 30: Permalloy; and Shape of the fixing member 50: 8 mm in width, 24 mm in length, 0.8 mm in thickness.

### COMPARATIVE EXAMPLE

When an external magnetic field with a magnetic flux density of 1 mT was given to a structure in a comparative example in which a magnetic sensor was mounted on the front surface of a circuit board and a portion above the magnetic sensor was covered with a U-shaped shield member, an increase of 1.7% was seen when compared with a case in which no external magnetic field was given.

The shape of each portion in the simulation in the comparative example was as follows:

Shape of the opposing portions of the shield member: 6 mm in width, 10 mm in length, 0.8 mm in thickness; and

Material of the shield member: Permalloy.

From the above results, it was clear that the influence of the external magnetic field on the current sensor 10 in the first embodiment is kept small when compared with the current sensor in the comparative example, and it was found that the current sensor in the first embodiment has high shield performance.

### Second Embodiment

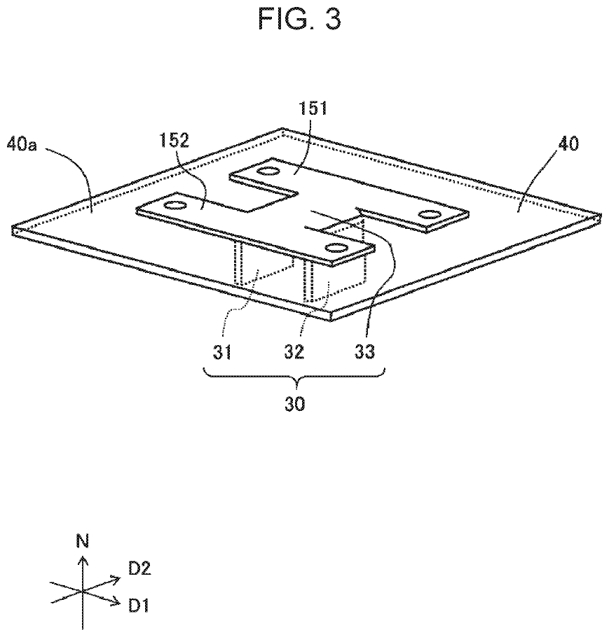

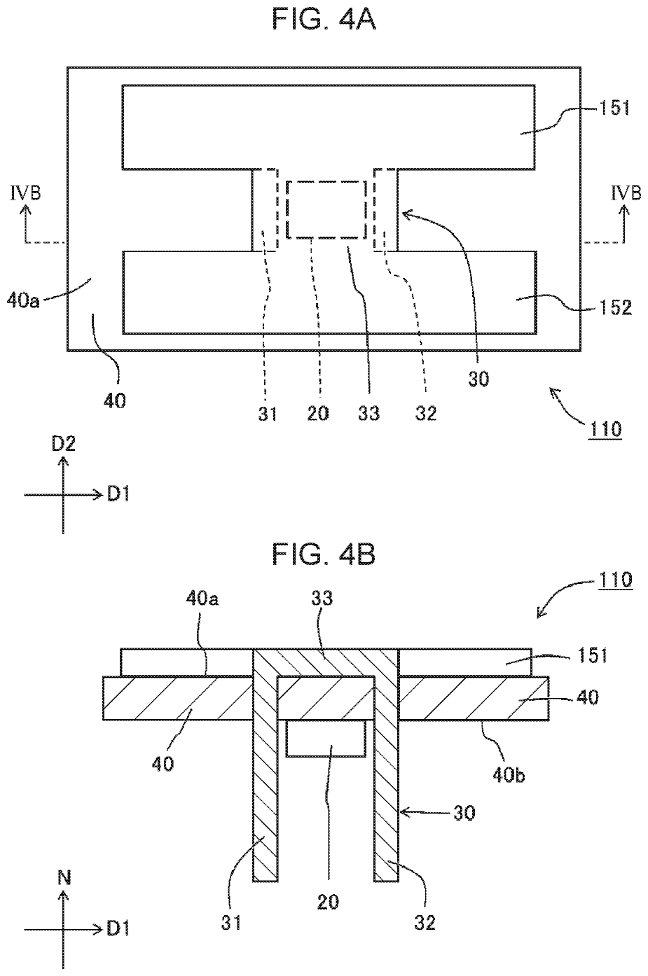

FIG. 3 is a perspective view illustrating the structure of a current sensor 110 according to a second embodiment. FIG. 4A is a plan view illustrating the structure of the current sensor 110 according to the second embodiment, and FIG. 4B is a sectional view along line IVB-IVB in FIG. 4A. In FIGS. 4A and 4B, the structure illustrated in FIG. 3 is simplified for convenience of explanation.

The second embodiment differs from the first embodiment in that two fixing members 151 and 152 may be provided on both sides of the shield member 30 in the second direction D2, one on each side. Other points in the structure are similar as in the first embodiment, and the same reference characters will be assigned to the same members.

With the current sensor 10 in the first embodiment, the fixing member 50 has been disposed only on one side of the shield member 30 in the second direction D2 when viewed along the normal direction N. With the current sensor 110 in the second embodiment, however, two fixing members 151 and 152 are disposed on both sides of the shield member 30 in the second direction D2, one on each side.

The first fixing member 151, the second fixing member 152, and shield member 30 are integrally formed from a single part. They are formed by bending a plate made of a similar magnetic material as in the first embodiment to a predetermined shape.

The first fixing member 151 and second fixing member 152 are provided so as to extend in parallel to each other in plan view, and are continuous to the linking portion 33 of the shield member 30 so as to form the same plane together with the linking portion 33. The first fixing member 151 and second fixing member 152 have the same shape: they are shaped like a rectangle shape extending in the first direction D1 in plan view. Each of the first fixing member 151 and second fixing member 152 extends to the outside of both sides of the linking portion 33 in the first direction D1 when viewed along the normal direction N.

The first fixing member 151 and second fixing member 152 are fixed to the circuit board 40 as with the fixing member 50 in the first embodiment. Therefore, the first fixing member 151, the second fixing member 152, and the linking portion 33 of the shield member 30 are in contact with the front surface 40a of the circuit board 40.

In the above structure, shield performance achieved by the two fixing members 151 and 152 is added to the shield performance in which the external magnetic field in the first direction D1 is blocked by the shield member 30, so the shield performance for the external magnetic field can be further enhanced. Due to fixing with both of the two fixing members 151 and 152, stability in fixing to the circuit board 40 can be further enhanced. Other functions, effects, and variations are similar as in the first embodiment.

Here, a simulation result in an example will be described about effects when an external magnetic field is given to the current sensor 110 in the second embodiment.

### Example 2

When an external magnetic field with a magnetic flux density of 1 mT was given to the current sensor 110 having a shape described below, an increase of 0.1% was seen when compared with a case in which no external magnetic field was given.

The shape of each portion in the simulation in example 2 was as follows:

Shape of the opposing plates 31 and 32: 6 mm in width, 10 mm in length, 0.8 mm in thickness;

Material of the shield member 30: Permalloy; and Shape of each of the fixing members 151 and 152: 8 mm in width, 24 mm in length, and 0.8 mm in thickness.

From this result, it was clear that the influence of the external magnetic field on the current sensor 110 in the second embodiment is kept small when compared with the current sensor in the comparative example described above, and it was found that the current sensor 110 has high shield performance.

### Third Embodiment

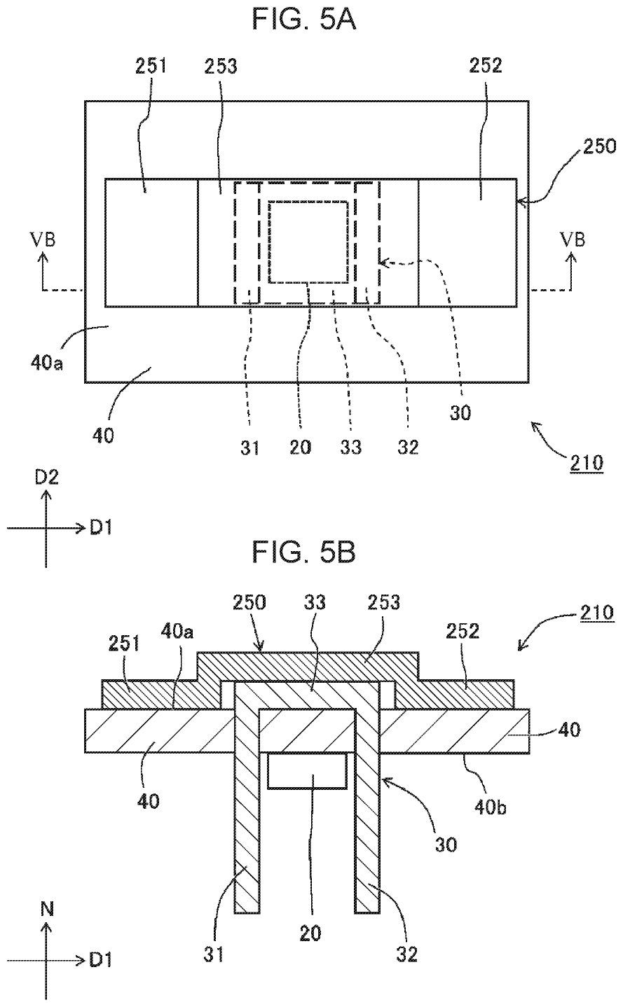

FIG. 5A is a plan view illustrating the structure of a current sensor 210 according to a third embodiment, and FIG. 5B is a sectional view along line VB-VB in FIG. 5A.

The third embodiment differs from the first embodiment in that a fixing member 250 is separated from the shield member 30 and that an intermediate portion 253 may be placed so as to be stacked on the linking portion 33 of the shield member 30 when viewed along the normal direction N. Other points in the structure are similar as in the first embodiment, and the same reference characters will be assigned to the same members.

The fixing member 250 is composed of a magnetic material. The fixing member 250 may have the intermediate portion 253 and two extending portions 251 and 252 extending from both sides of the intermediate portion 253 in the first direction D1. The intermediate portion 253 and extending portions 251 and 252 are formed by, for example, being molded or stamping a plate. As illustrated in FIG. 5B, the fixing member 250 has a stepped shape so that the two extending portions 251 and 252 are brought into contact with the front surface 40a of the circuit board 40 and the intermediate portion 253 is brought into contact with the front surface of the linking portion 33 of the shield member 30.

The fixing member 250 is fixed to the circuit board 40 by, for example, forming through-holes passing through the extending portions 251 and 252 in their thickness direction, inserting fixing screws in the through-holes, and screwing the fixing screws into the circuit board 40. Due to this fixing, the intermediate portion 253 abuts the linking portion 33 of the shield member 30, fixing the shield member 30 with the linking portion 33 in contact with the circuit board 40.

It is also possible for the fixing member 250 to have a structure in which the extending portions 251 and 252 and the circuit board 40 are fixed to each other by placing an adhesive between the extending portions 251 and 252 and the circuit board 40 instead of the above fixing screws or in addition to the fixing screws. Furthermore, the intermediate portion 253 and linking portion 33 may be fixed to each other with screws or an adhesive.

The above structure enables the fixing member 250 and shield member 30 to be simply formed. Other functions, effects, and variations are similar as in the first embodiment.

Here, a simulation result in an example will be described about effects when an external magnetic field is given to the current sensor 210 in the third embodiment.

### Example 3

When an external magnetic field with a magnetic flux density of 1 mT was given to the current sensor 210 having a shape described below, an increase of less than 0.1% was seen when compared with a case in which no external magnetic field was given.

The shape of each portion in the simulation in example 3 was as follows:

Shape of the opposing plates 31 and 32: 8 mm in width, 24 mm in length, 0.8 mm in thickness;

Material of the shield member 30: Permalloy; and Shape of the fixing member 250: 8 mm in width, 24 mm in length, 0.8 mm in thickness.

From the above result, it was clear that the influence of the external magnetic field on the current sensor 210 in the third embodiment is kept small when compared with the current sensor in the comparative example described above, and it was found that the current sensor 210 has high shield performance.

### Fourth Embodiment

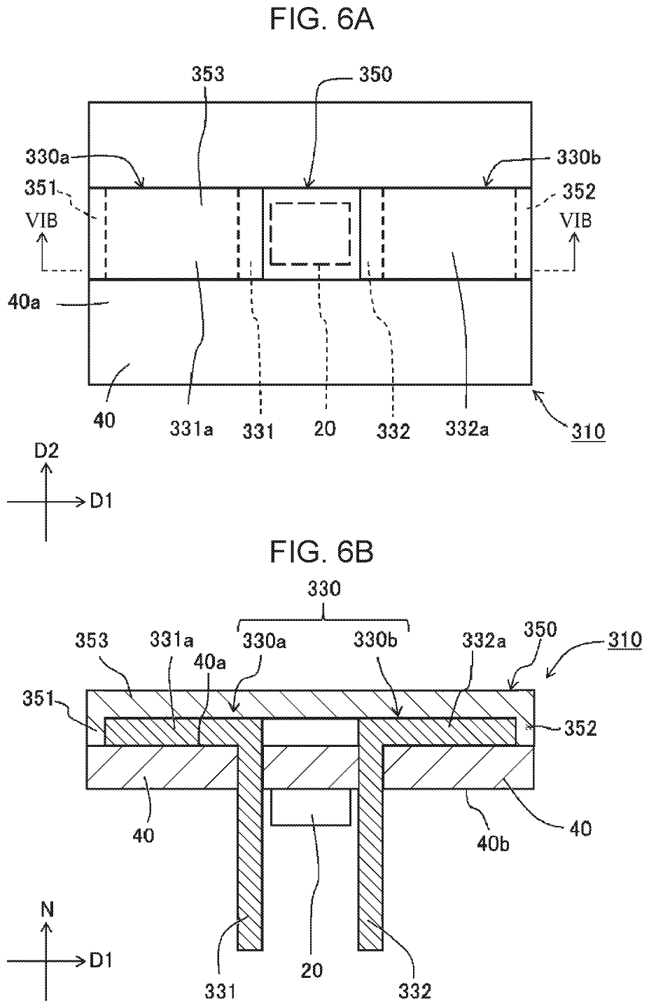

FIG. 6A is a plan view illustrating the structure of a current sensor 310 according to a fourth embodiment, and FIG. 6B is a sectional view along line VIB-VIB in FIG. 6A. The fourth embodiment differs from the first embodiment in that two opposing plates 331 and 332 are provided so as not to be linked together above the magnetic sensor 20 but two shield members 330a and 330b, which may be independent of each other, may be linked together through a fixing member 350, which is separated from the two shield members 330a and 330b. Other points in the structure are similar as in the first embodiment, and the same reference characters will be assigned to the same members.

A shield member 330 has a first shield member 330a and a second shield member 330b. These shield members 330a and 330b each have a shape formed by bending a plate composed of a magnetic material similar as with the shield member 30 in the first embodiment to an L-shape when viewed from the side. These shield members 330a and 330b are placed so that the opposing plate 331 of the first shield member 330a and the opposing plate 332 of the second shield member 330b face each other in the first direction D1 with the magnetic sensor 20 interposed between the opposing plate 331 and the opposing plate 332. The two opposing plates 331 and 332 are placed so as to pass through from the front surface 40a of the circuit board 40 to its rear surface 40b in the thickness direction of the circuit board 40 and to further extend, as with the two opposing plates 31 and 32 in the first embodiment. Support portions 331a and 332a respectively extend from the upper ends of the two opposing plates 331 and 332 along the first direction D1 so as to be separated from each other. The two support portions 331a and 332a are placed along the front surface 40a of the circuit board 40.

The fixing member 350, which is separated from the shield members 330a and 330b, is placed on the support portions 331a and 332a in contact with them so as to cover them from above. The fixing member 350 is composed of a magnetic material similar as with the shield members 330a and 330b. The fixing member 350 has an intermediate portion 353, which is positioned above the magnetic sensor 20 so as to extend along the first direction D1, and also has two extending portions 351 and 352 extending from both sides of the intermediate portion 353 in the first direction D1, one from each side. As illustrated in FIG. 6B, the fixing member 350 has a stepped shape so that the two extending portions 351 and 352 are brought into contact with the front surface 40a of the circuit board 40 and the intermediate portion 353 is brought into contact with the front surfaces of the support portions 331a and 332a of the two shield members 330a and 330b.

The fixing member 350 is fixed to the circuit board 40 by, for example, screwing fixing screws, which are passed through the extending portions 351 and 352 in the normal direction N, into the circuit board 40. Due to this fixing, the intermediate portion 353 abuts the support portions 331a and 332a, fixing the two shield members 330a and 330b in contact with the circuit board 40.

This type of structure enables the fixing member 350 to be more simply manufactured. Moreover, since a portion above the magnetic sensor 20 is covered with the fixing member 350 composed of a magnetic material, an external magnetic field from above can be blocked. Other functions, effects, and variations are similar as in the first embodiment.

The present invention has been described with reference to the above embodiments, but the present invention is not limited to the above embodiments. It is possible to improve or change the present invention within the range of the object of improvement or the concept of the present invention.

1. A current sensor comprising:
a circuit board having a surface parallel to a first direction;
a magnetism detection unit mounted on the circuit board, the magnetism detection unit being configured to detect a first component of a magnetic field in the first direction, the magnetic field being generated by a current flowing through a current path;
a shield member configured to shield the magnetism detection unit from an external magnetic field, the shield member including a pair of opposing plates facing each other in the first direction, such that the magnetism detection unit is interposed between the pair of opposing plates;
and
a fixing member for fixing the shield member to the circuit board, the fixing member extending along the circuit board on both sides of the magnetism detection unit in the first direction when viewed from a normal direction normal to the surface of the circuit board.

2. The current sensor according to claim 1, wherein the shield member includes a linking portion that couples respective ends of the two opposing plates together.

3. The current sensor according to claim 1,
wherein the fixing member is provided on at least one side of the shield member in a second direction orthogonal to the first direction when viewed from the normal direction, the second direction being parallel to the surface of the circuit board; and
wherein the fixing member and the shield member are integrally formed as a single part.

4. The current sensor according to claim 3, wherein the fixing member is provided on both sides of the shield member in the second direction when viewed from the normal direction.

5. The current sensor according to claim 2,
wherein the fixing member includes:
a middle portion; and
a pair of extending portions extending from the middle portion toward both sides of the magnetism detection unit in the first direction, when viewed from the normal direction, such that the middle and portion couples the pair of extending portions together, and
wherein the fixing member and the shield member are connected together via the linking portion and the middle portion.

6. The current sensor according to claim 5, wherein the middle portion is stacked over the linking portion in the normal direction.

7. The current sensor according to claim 1, wherein the pair of opposing plates are two independent parts which are coupled together through the fixing member.

8. The current sensor according to claim 2,
wherein the circuit board has a front surface, and a rear surface parallel to the front surface; and
wherein the magnetism detection unit is disposed on one of the front and rear surfaces, while the linking portion of the shield member is disposed on the other of the front and rear surfaces.

9. The current sensor according to claim 1, wherein the current path is formed on the circuit board as a circuit pattern.
